(19) United States
(12) Patent Application Publication
(10) Pub. No.: US 2013/0106490 A1
(43) Pub. Date: May 2, 2013

(54) DEBOUNCE SWITCHING ELEMENT INCORPORATING A DEBOUNCE CIRCUIT

(71) Applicant: Soonghwan Ro, Daejeon (KR)

(72) Inventor: Soonghwan Ro, Daejeon (KR)

(21) Appl. No.: 13/810,077

(22) PCT Filed: Jul. 13, 2010
(86) PCT No.: PCT/KR2010/004554

§ 371 Date: Jan. 14, 2013

(51) Int. Cl. H03K 17/96

(52) U.S. Cl. CPC H03K 17/96
USPC 327/385

(57) ABSTRACT

Provided is A switching device including a button; a plate spring installed under the button; a debounce circuit that electrically removes bounce generated by a physical elasticity when switching turns on and off; at least three terminal pins that include a first terminal pin, a second terminal pin, and a third terminal pin connected to the debounce circuit; and a switch body that include the debounce circuit and an opening portion through which the plate spring and the button are mounted on the switch body, wherein the debounce circuit includes a first output terminal connected to the first terminal pin, a supply voltage terminal receiving a supply voltage and connected to the second terminal pin, and a ground terminal connected to the third terminal pin, wherein the first contact point is connected to the second contact point when the button and the plate spring are pushed.

### BACKGROUND

1. Technical Field

The present invention relates to a switch, particularly a debounce switching device having an embedded debounce circuit which electrically removes bounce generated by a physical elasticity when a mechanical switch turns on or off by a contact.

2. Related Art

In general, a mechanical switch is turned on or off by a metal contact. Such a metal contact makes bounce generated by a physical elasticity. When the turn-on or turn-off of the mechanical switch is used as an input of an electrical turn-on or turn-off, it is converted into an electrical signal with a pulse type. Thus, a debounce circuit removing the bounce should be externally added to the mechanical switch. However, it is cumbersome, needs an additional device, occupies a wide space, and increases a manufacturing cost because the debounce circuit configures an additional circuit.

### SUMMARY

It is an object of a present invention to provide a bounce switching device having an embedded debounce circuit which electrically removes bounce generated by a physical elasticity when a mechanical switch is turned on or off by a contact, does not need an additional debounce circuit, and reduces a space and a manufacturing cost.

An aspect of the present invention provides a switching device having an embedded debounce circuit includes a switching member that connects and disconnects a first contact point with a second contact point by an external force; a debounce circuit chip that electrically removes bounce generated by a physical elasticity when the switching member is turned on and turned off, and is connected to the first contact point and the second contact point; a supply voltage terminal pin connected to the first contact point; a ground terminal pin connected to the second contact point; a plurality of terminal pins that is connected to output pins of the debounce circuit chip; and a switch body on which the debounce circuit chip is mounted and in which the plurality of terminal pins and the switching member are installed.

Another aspect of the present invention provides a switching device having an embedded debounce circuit includes a button; a plate spring installed under the button; a debounce circuit that electrically removes bounce generated by a physical elasticity when switching turns on and off; at least three terminal pins that include a first terminal pin, a second terminal pin, and a third terminal pin connected to the debounce circuit; and a switch body that include the debounce circuit and an opening portion through which the plate spring and the button are mounted on the switch body, wherein the debounce circuit includes a first output terminal connected to the first terminal pin, a supply voltage terminal receiving a supply voltage and connected to the second terminal pin, and a ground terminal connected to the third terminal pin, wherein the first contact point is connected to the second contact point by a pressing force of the pan spring generated when the button is pushed, wherein the first contact point is disconnected from the second contact point by a restoring force of the plate spring generated when the button are not pushed, wherein the first contact point is connected to the supply voltage terminal, and wherein the second contact point is connected to the ground terminal.

According to a debounce switching device having an embedded debounce circuit of the present invention, it is convenient for a user to layout a circuit using a switch, and debounce can be efficiently removed by embedding the best appropriate circuit for a debounce characteristics generated by a mechanical contact of the switch, thereby improving the characteristics of the whole circuit.

In addition, it is not necessary to use an additional debounce circuit in the debounce switching device, thereby reducing a space and a manufacturing cost.

### BRIEF DESCRIPTION OF THE DRAWINGS

FIG. 1 illustrates an internal structure of a push button switch without a debounce circuit chip.

FIG. 2 illustrates an internal structure of a debounce switching device having an embedded debounce circuit according to an embodiment of the present invention.

FIG. 3 illustrates an embodiment of the debounce circuit illustrated in FIG. 1.

FIG. 4 illustrates an embodiment of a circuit to which the push button switch according to the present invention is applied.

FIG. 5 illustrates debouncing generated in the push button switch.

### DESCRIPTION OF EXEMPLARY EMBODIMENTS

Hereinafter, preferable embodiments of the present invention will be described with reference to the drawings. The embodiments described in the present specification and the configurations illustrated in the drawings are merely preferable embodiments of the present invention, and do not all cover the technical spirit of the present invention. Thus, it is to be understood that various equivalents and modifications capable of replacing them can exist at the time of application of the present invention.

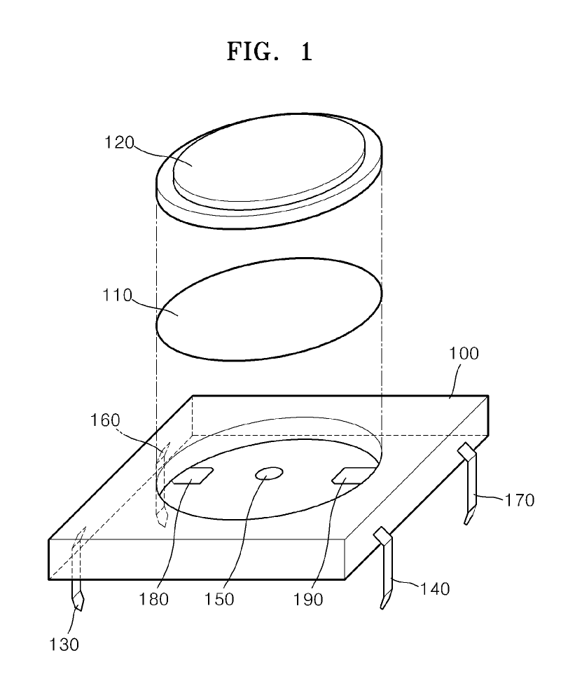

FIG. 1 illustrates an internal structure of a push button switch without a debounce circuit chip. Referring to FIG. 1, the push button switch includes a switch body 100, a conductive plate spring 110, and a button 120. The switch body 100 has a first switch terminal pin 130 and a second switch terminal pin 140 connected to each other. Both pins 130 and 140 are connected to a first contact point 150 inside the switch body 100. In addition, a third switch terminal pin 160 is connected to a fourth switch terminal pin 170. Both pins 160 and 170 are connected to a second contact point 180 and a third contact point 190.

Because the convex plate spring 110 is contacted with only the second and third contact points 180 and 190 in a state where the button 120 is not pushed, the first contact point 150 is not contacted with the second and third contact points 180 and 190. However, if the button 120 is pushed, the convex plate spring 110 is thrust downward, thereby contacting the first contact point 150 with the second and third contact points 180 and 190.

Accordingly, the first and second switch terminal pins 130 and 140 are connected to the third and fourth switch terminal pins 160 and 170, thereby generating a switching operation. If the button 120 is released, the first contact point 150 is disconnected from the second and third contact points 180 and 190 by a restoring force of the plate spring 110, thereby the first and second switch terminal pins 130 and 140 are disconnected from the third and fourth switch terminal pins 160 and 170.

The switching device having an embedded debounce circuit according to the present invention includes a switching member, a debounce circuit chip, multiple terminal pins, and the switch body. The switching member connects or disconnects a first contact point of a switching with a second contact point of the switching by an external force. The debounce chip is configured by one chip which includes all of the debounce circuit. The debounce chip can be configured by a different kind of circuit by using at least one resistor and at least one capacitor.

The debounce circuit electrically removes bounce generated by a physical elasticity when switched on or off by the switching member, and is connected to the first contact point of the switch and the second contact point of the switch, respectively. The multiple terminal pins include a supply voltage terminal VCC connected to the first contact point of the switch, a ground terminal pin connected to the second terminal point of the switch, and an output terminal pin connected to an output terminal of the debounce circuit. The multiple terminal pins can further include other output terminal having a reverse relation with the output terminal of the debounce circuit, in other words, outputting “1” when the output terminal of the debounce circuit is “0”, and “0” when the output terminal of the debounce circuit is “1”. The debounce circuit chip is mounted on the switch body, and the multiple terminal pins and the switching member are installed in the switch body.

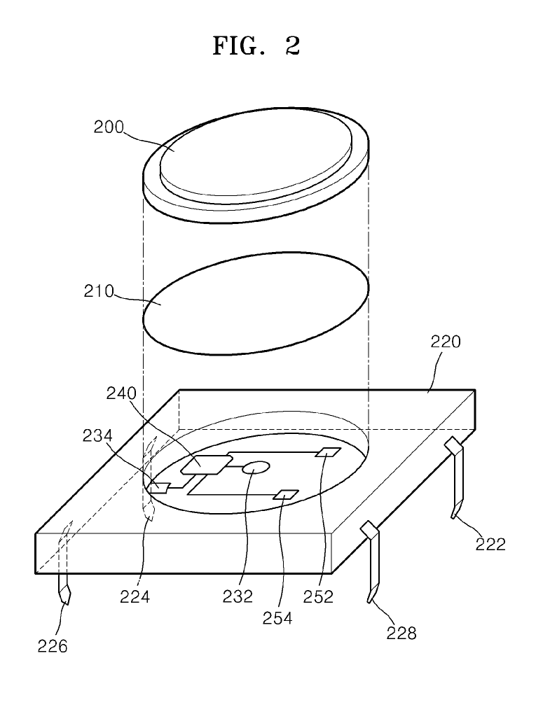

FIG. 2 illustrates an internal structure of a debounce switching device having an embedded debounce circuit according to an embodiment of the present invention. The embodiment of the present invention illustrated in FIG. 2 is a kind of push button switch, and includes a button 200, a plate spring 210, a debounce circuit chip 240, multiple terminal pins 222, 224, 226 and 228, and a switch body 220.

The button 200 is provided to switch on or off. If the button 200 is pushed, the plate spring 210 installed under the button 200 is pushed, thereby switching is turned on. If the button 220 is released, the plate spring 210 is restored, thereby switching is turned off. The plate spring 210 is installed under the button 200. Thus, if the button 200 is pushed, the switch is turned on, and if the button 200 is not pushed, the switch is turned off by the restoring force. The debounce circuit chip is configured by one chip which includes the debounce circuit electrically removing the bounce generated by the physical elasticity when switched is turned on or off.

The multiple terminal pins 222, 224, 226 and 228 include at least a first terminal pin 222, a second terminal pin 224, and a third terminal pin 226, and can further includes a fourth terminal pin 228. The first terminal pin 222 is a connected to a first output terminal 252, and the fourth terminal pin 228 is connected to a second output terminal 254 which is inversely related to the first output terminal 252. The second terminal pin 224 is connected to the supply voltage terminal VCC. A supply voltage is supplied to the debounce circuit. The third terminal pin 226 is connected to a ground terminal GND of the debounce circuit through a first contact point 234 of the switch.

The debounce circuit chip 240 is embedded in the switch body 220, and the switch body 220 includes an opening portion through which the plate spring 210 and the button 200 is mounted thereon. As described in the embodiment, it is preferable to mount the debounce circuit chip 240 on the switch body 220, however the debounce circuit can be embedded inside the switch body 220.

The plate spring 210 is pushed by pushing the button 200, thereby the contact point 232 is connected to the contact point 234. If the button 200 is not pushed, the contact point 232 is disconnected from the contact point 234 by restoring of the plate spring 210, the contact point 232 is connected to an end 232 of a resistor R2, and the contact point 234 is connected to the ground terminal GND.

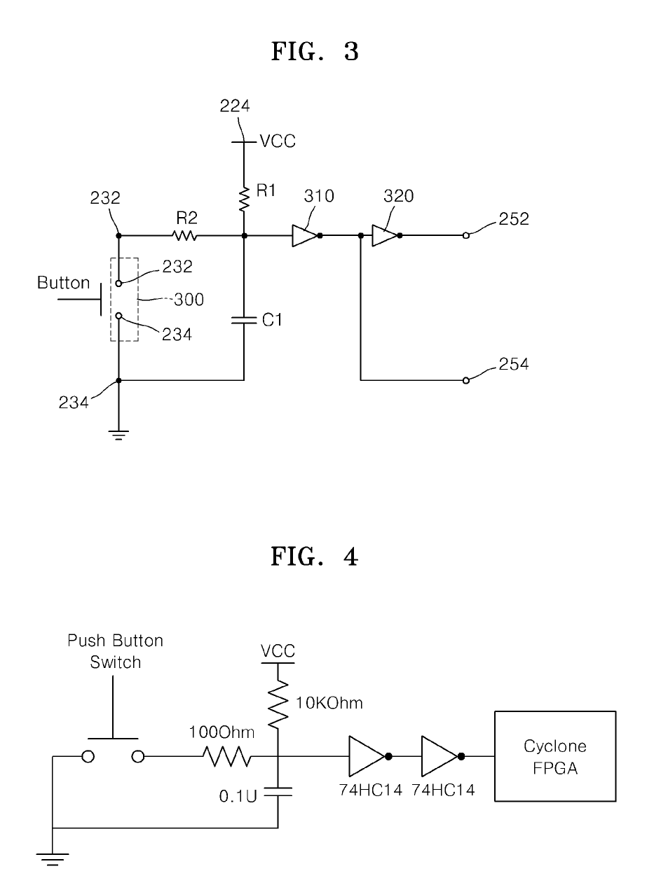

When the button 200 is pushed, the contact point 232 is connected to the contact point 234 by the plate spring 210, thereby the debounce circuit outputs a signal through the first output terminal 252 and the second output terminal 254. For example, if the embedded debounce circuit is configured as illustrated in FIG. 3, the contact point 232 of the switch is connected to the contact point 234 of the switch by the plate spring 210 when the button 200 is pushed, thereby a logic value “0” is output to the first output terminal 252 and a logic value “1” is output to the second output terminal 254. But, in a state where the button 200 is not pushed, the logic value “1” is output to the first output terminal 252 and an inverse logic value is output to the second output terminal 254.

FIG. 3 illustrates an embodiment of the debounce circuit. The present invention is not limited to the debounce circuit illustrated in FIG. 3, various modifications can be done, and the present is not limited thereto. The debounce circuit illustrated in FIG. 3 includes two output terminals 252 and 254, two inverters 310 and 320, two resistors R1 and R2, one capacitor C1, and a switching portion 300.

The two output terminals are configured by a first output terminal 252, and a second output terminal 254 which is inversely related to the first output terminal 252. The first output terminal 252 is connected to the first terminal pin 222, and the second output terminal 254 is connected to the fourth terminal pin 228.

The debounce circuit includes the supply voltage terminal VCC which is connected to the second terminal pin 224 to which a supply voltage is applied, and the ground terminal GND which is connected to the third terminal pin 226 to which a ground voltage is applied.

A first end of the resistor R1 is connected to the supply voltage terminal VCC, and the second end of the resistor R1 is connected to the resistor R2, the capacitor C1, and an input terminal of the inverter 310.

The output terminal of the inverter 310 is connected to the second output terminal 254. An output terminal of the inverter 320 is connected to the first output terminal 252 and inputs the output of the inverter 310.

An end of the capacitor C1 is connected to the ground terminal GND, and the second end of the capacitor C1 is connected to the input terminal of the inverter 310. An end of the resistor R2 is connected to the input terminal of the inverter 310, the second end of the capacitor C1, and the second end of the resistor R1, and the second end of the resistor R2 is connected to the contact point 232 of the switch.

The switching portion 300 includes a first contact point 232 which is connected to the second end of the resistor R2, and the second switching contact point 234 which is connected to the ground terminal GND. When the plate spring 210 is pushed, the first contact point is connected to the second contact point of the switching. If the plate spring 210 is not pushed, the first contact point is disconnected from the second switching contact point.

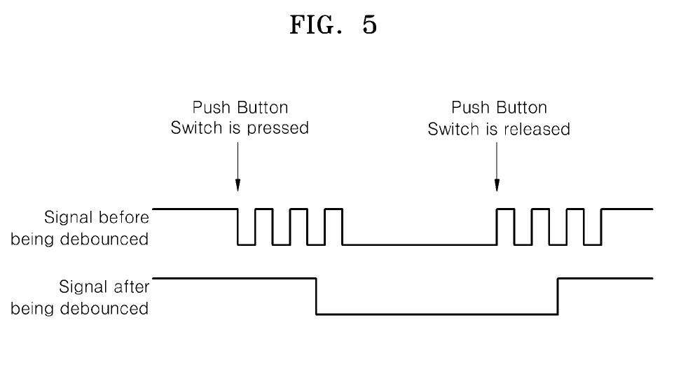

An example of a circuit to which the push button switch according to an embodiment of the present invention can be applied may be configured as illustrated in FIG. 4. FIG. 5 illustrates debouncing of the push button switch. The supply voltage uses 3.3 volt. In a state where the switch is not pushed, an output voltage of the switch is maintained as 3.3 volt. However, when the switch is pushed, the output voltage of the switch drops to 0 (zero) volt. At this time, chattering occurs in an output stage. The chattering is removed by the debounce circuit illustrated in FIG. 4. FIG. 5 illustrates a signal in which the chattering occurred by the switch and a signal after debounced. There are total 16 push button switches, key values of 0x0 to 0xF are assigned to each switch, and each switch is connected to a general-purpose input and output pin of FPGA through the debounce circuit.

The present invention is described with reference to the embodiments illustrated in the drawings, but they are merely exemplary things, and it is to be understood that those skilled in the art can make various modifications, changes, and equivalents. Thus, the technical protection scope of the present invention should be determined by the technical spirit of the attached claim scope.

What is claimed is:

1. A switching device having an embedded debounce circuit comprising:
a switching member that is connected and disconnected a first contact point with a second contact point by an external force;
a debounce circuit chip that electrically removes bounce generated by a physical elasticity when the switching member is turned on and turned off, and is connected to the first contact point and the second contact point;
a plurality of terminal pins that include a supply voltage terminal pin connected to the first contact point, a ground terminal pin connected to the second contact point, and output terminal pins connected to the debounce circuit chip; and
a switch body on which the debounce circuit chip is mounted and in which the plurality of terminal pins and the switching member are installed.

2. A switching device having an embedded debounce circuit comprising:
a button;
a plate spring installed under the button;
a debounce circuit that electrically removes bounce generated by a physical elasticity when switching turns on and off;
at least three terminal pins that include a first terminal pin, a second terminal pin, and a third terminal pin connected to the debounce circuit; and
a switch body that include the debounce circuit and an opening portion through which the plate spring and the button are mounted on the switch body,
wherein the debounce circuit includes a first output terminal connected to the first terminal pin, a supply voltage terminal receiving a supply voltage and connected to the second terminal pin, and a ground terminal connected to the third terminal pin,
wherein the first contact point is connected to the second contact point by a pressing force of the pan spring generated when the button is pushed,
wherein the first contact point is disconnected from the second contact point by a restoring force of the plate spring generated when the button are not pushed,
wherein the first contact point is connected to the supply voltage terminal, and
wherein the second contact point is connected to the ground terminal.

3. The switching device according to claim 2, wherein the debounce circuit is embedded in the form of one chip in the switch body.

4. The switching device according to claim 3,
wherein the debounce circuit further includes a second output terminal that has inverse relation to the first output terminal, and
wherein the switching device further includes a fourth terminal pin connected to the second terminal pin.

5. The switching device according to claim 4,
wherein the debounce circuit further includes a first resistor connected to the supply voltage terminal;
a first inverter whose output terminal is connected to the first output terminal;
a second inverter whose output terminal is connected to the second output terminal of the debounce circuit and that inputs the output of the first inverter;
a capacitor whose first end is connected to the ground terminal and whose a second end is connected to the input terminal of the first inverter;
a second resistor whose first end is connected to the input terminal of the first inverter, the second end of the capacitor , and the second end of the first resistor, whose second end is connected to the first contact point ; and
a switching portion whose first contact point connected to the second end of the second resistor, and whose second contact point connected to the ground terminal, wherein the first contact point is connected to the second contact point when the pan spring is pressed, and the first contact point is disconnected from the second contact point when the plate spring are not pressed.
